(19) United States
(12) Patent Application Publication
(10) Pub. No.: US 2014/0134792 A1
(43) Pub. Date: May 15, 2014

(54) Solution-Processed Metal Selenide Semiconductor using Deposited Selenium Film

(71) Applicants: Sean Andrew Vail, Vancouver, WA (US); Alexey Koposov, Vancouver, WA (US); Wei Pan, Vancouver, WA (US); Gary D. Foley, Portland, OR (US); Jong-Jan Lee, Camas, WA (US)

(72) Inventors: Sean Andrew Vail, Vancouver, WA (US); Alexey Koposov, Vancouver, WA (US); Wei Pan, Vancouver, WA (US); Gary D. Foley, Portland, OR (US); Jong-Jan Lee, Camas, WA (US)

(21) Appl. No.: 13/719,052

(22) Filed: Dec. 18, 2012

Related U.S. Application Data
(63) Continuation-in-part of application No. 13/711,356, filed on Dec. 11, 2012.
Application No. 13/711,356 is a continuation-in-part of application No. 13/674,005, filed on Nov. 10, 2012.

(51) Int. Cl. H01L 21/02

(52) U.S. Cl. CPC H01L 21/02628
USPC 438/102

(57) ABSTRACT

Methods are provided for fabricating a solution-processed metal and mixed-metal selenide semiconductor using a selenium (Se) film layer. One aspect provides a conductive substrate and deposits a first Se film layer over the conductive substrate. A first solution, including a first material set of metal salts, metal complexes, or combinations thereof, is dissolved in a solvent and deposited on the first Se film layer. A first intermediate film comprising metal precursors is formed from corresponding members of the first material set. In one aspect, a plurality of intermediate films is formed using metal precursors from the first material set or a different material set. In another aspect, a second Se film layer is formed overlying the intermediate film(s). Thermal annealing is performed in an environment including hydrogen (H₂), hydrogen selenide (H₂Se), or Se/H₂. The metal precursors are transformed in the intermediate film(s), and a metal selenide-containing semiconductor is formed.

### RELATED APPLICATION

The application is a Continuation-in-Part of an application entitled, ELECTROCHEMICAL SYNTHESIS OF SELENIUM NANOPARTICLES, invented by Wei Pan et al., Ser. No. 13/711,356, filed on Dec. 11, 2012, Attorney Docket No. SLA3219;

which is a Continuation-in-Part of an application entitled, SOLUTION-PROCESSED METAL SELENIDE SEMICONDUCTOR USING SELENIUM NANOPARTICLES, invented by Sean Vail et al., Ser. No. 13/674,005, filed on Nov. 10, 2012, Attorney Docket No. SLA3211. The above-mentioned applications are incorporated herein by reference.

### BACKGROUND OF THE INVENTION

1. Field of the Invention

This invention generally relates to metal selenide-containing semiconductors and, more particularly, to processes for forming metal selenide-containing semiconductors using solutions of metal precursors and a deposited Se film layer.

2. Description of the Related Art

Metal and mixed-metal selenides represent important classes of semiconductor materials for electronic and photovoltaic (PV) applications. In particular, copper indium gallium diselenide (CuInₗ₋ₓGaₓSe₂ or CIGS) has emerged as a promising alternative to existing thin-film technologies. Overall, CIGS thin films possess a direct and tunable energy band gap, high optical absorption coefficients in the visible to near-infrared (NIR) spectrum, and have demonstrated power conversion efficiencies (PCEs) ˜20%.

Conventional CIGS fabrication (vacuum) processes typically involve either sequential or co-evaporation (or sputtering) of copper (Cu), indium (In), and gallium (Ga) metal onto a substrate followed by annealing in an atmosphere containing a selenium (Se) vapor source to provide the final CIGS absorber layer structure.

In contrast to vacuum approaches, which create an environment to control variables such as the gases introduced and pressure, non-vacuum methods offer significant advantages in terms of both reduced cost and high throughput manufacturing capability via roll-to-roll processing. Electrodeposition or electroplating of metals (from metal ions in solution) onto conductive substrates represents an alternative CIGS fabrication strategy. Finally, CIGS fabrication via deposition of mixed binary, ternary, and/or quaternary nanoparticles of copper, indium, gallium, and selenium (so called nanoparticle “inks”) embodies another non-vacuum approach.

In general, CIGS fabrication via solution-processed approaches (non-nanoparticle) offers a convenient, low-cost alternative. According to this method, metal precursors of Cu, In, Ga, and optionally Se, are contained in a solvent to form a solubilized CIGS ink and subsequently deposited on a substrate to form a film using conventional methods. In many cases, post-selenization is required in order to compensate for both Se deficiencies in the solution-based formulation and/or the loss of Se during subsequent thermal processing of the as-deposited CIGS absorber layer.

A number of solution-based approaches to CIGS have been provided as suitable alternatives to both vacuum processes and electrodeposition approaches. Such mentionable technologies include solutions of metal precursors dissolved in hydrazine,¹ hydrazine-free deposition using isolated hydrazinium-based precursors,² aqueous strategies using metal chalcogenide precursors in combination with labile sources of Se or sulfur (S),³ and deposition of low-cost, air-stable precursor solutions of Cu, In and Ga containing materials.^{4,5} The deposition of Se films can be realized through several processing options including chemical bath deposition (CBD),⁶electrochemical deposition,⁷ and/or conventional approaches including thermal evaporation, among others.

Unfortunately, most conventional CIGS fabrication strategies require high temperature post-selenization following deposition of the Cu—In—Ga layer. Even in those cases where selenium is integrated before/during the film deposition stage (as in Se containing nanoparticles or solution based processes with thermally labile Se sources), selenium losses during high temperature processing can render the resultant CIGS film as selenium deficient. In particular, an inability of the selenium source vapor to penetrate deep into a deposited Cu—In—Ga film can result in reduced grain size, poor overall absorber layer uniformity, and/or morphology as well as poor interfacial contacts, the effects from which are manifested in terms of reduced CIGS solar cell performance.

Typically, selenium cannot be practically employed in a solution-based approach as a powder (or other pristine form) due to a lack of solubility and/or ability to form a stable dispersion without exhaustive measures. Conceivably, although soluble chemical complexes of Se can be provided for solution-based processes, the concentration of Se is often only modest in the final mixture, in addition to introducing additional CIGS film contamination (from ligands) following thermal processing. A parent application, entitled SOLUTION-PROCESSED METAL SELENIDE SEMICONDUCTOR USING SELENIUM NANOPARTICLES, invented by Sean Vail et al., Ser. No. 13/674,005, filed on Nov. 10, 2012, describes a technology for providing a vehicle for selenium delivery in solution-based processing with metal containing precursors of Cu, In and Ga via selenium nanoparticles (SeNPs). Another parent application, entitled ELECTROCHEMICAL SYNTHESIS OF SELENIUM NANOPARTICLES, invented by Wei Pan et al., Ser. No. 13/711,356, filed on Dec.11,2012, describes a process for synthesizing SeNPs by an electrochemical method that eliminates the requirement for a separate chemical reducing agent.

Bindu et. al demonstrated the deposition of Se on glass and tin oxide-coated glass via CBD from dilute solutions of sodium selenosulfate adjusted to acidic pH.⁸ Subsequently, an In layer was deposited on the Se film by vacuum evaporation followed by annealing to afford indium selenide (In₂Se₃). Films of copper indium diselenide (CuInSe₂) were fabricated through a similar method in which layers of in and Cu were sequentially evaporated onto Se films deposited by CBD.⁹ Finally, selenide films of silver (Ag₂Se), tin (SnSe₂), indium (In₂Se₃), copper (CuSe/Cu₂₋ₓSe), antimony (Sb₂Se₃), etc. were prepared using CBD deposited Se films.¹⁰ In these cases, the deposition of Se and the evaporation of metals were performed on separate substrates, Next, the Se and metal were held in contact and annealed to afford the metal selenides. Interestingly, a photovoltaic device structure of SnO₂:F—CdS—Sb₂S₃—AgSbSe₂ fabricated through this method demonstrated an open-circuit voltage (V_{oc})>500 mV and short-circuit current density (Jsc) ˜2-5 mA/cm². Overall, although the aforementioned describe an environmentally benign process for preparing a Se film, the approach and processes for deposition of metal components (evaporation) to contact the Se substrate deviate significantly from the processing strategy presented herein.

In 1991, Eherspacher et, al described a method for fabricating group compound semiconductors such as CuInSe₂ for thin-film, heterojunction PV devices.¹¹ Subsequent to deposition of Cu and In (and optionally other group IIIA metals), a film of Se is deposited (on top) followed by heating in a hydrogen containing atmosphere. However, deposition of selenium on top of a pre-deposited film of metal(s) may not provide a beneficial impact from selenium at greater film depth for CIGS growth. In particular, this approach does not include providing a source of selenium at the CIGS-Mo interface, which is important for realizing good interfacial contact.

Sferlazzo et. al provided an apparatus and method for depositing CIGS thin-films.¹² In general, the approach involves sequential deposition of a first layer of composite metal followed by selenium with subsequent selenization. Furthermore, additional layers (metal, then Se) may be deposited and selenized between incremental layer depositions. In addition, an apparatus for realizing a process flow using this methodology is disclosed. Finally, Aksu et. al described a method for fabricating a Group IBIIIAVIA absorber layer on a base for manufacturing a solar cell.¹³ The strategy involves deposition of a first metallic layer of at least one material selected from Cu, In, and Ga. Next, a selenium film is deposited on the first metallic layer followed by electrodeposition of a so called “interlayer” (gold and silver) which suppresses dissociation of selenium during the subsequent deposition of a second metallic layer.
1. D. B. Mitzi, W. Liu and M. Yuan, “Photovoltaic Device with Solution-Processed Chalcogenide Absorber Layer”, US2009/0145482 A1
2. D. B. Mitzi and matthew W. Copel, “Hydrazine-Free Solution Deposition of Chalcogenide Films”, U.S. Pat. No. 8,134,150 B2
3. Douglas A. Keszler and Benjamin L. Clark, “Metal Chalcogenide Aqueous Precursors and Processes to Form Metal Chalcogenide Films”, US2011/0206599 A1
4. Wei Wang, Yu-Wei Su and Chih-hung Chang, “Inkjet Printed Chalcopyrite CuInₓGa₁₋ₓSe₂ Thin Film Solar Cells”, Solar Energy Materials & Solar Cells 2011, 95, 2616-2620.

5. W. Wang, S-Y. Han, S- J. Sung. D-H. Kim and C-H. Chang, “8.01% CuInGaSe2 Solar Cells Fabricated by Air-Stable Low-Cost Inks”, Physical Chemistry Chemical Physics 2012, 14, 1115441159.
6. Biljana Pejova and Ivan Grozdanov, “Solution Growth and Characterization of Amorphous Selenium Thin Films Heat
Transformation to Nanocrystalline Gray Selenium Thin Films”, Applied Surface Science 2001, 177, 152-157.
7. Serdar Aksu, Yongbong Han and Bulent M. Basol, “Selenium Electroplating Chemistries and Methods”, US20090283411 A1.
8. K. Bindu, M. Lakshmi, S. Bini, C. Sudha Kartha, K. P. Vijayakumar, T. Abe and Y. Kashiwaba, “Amorphous Selenium Thin Films Prepared Using Chemical Bath Deposition: Optimization of the Deposition Process and Characterization”, Semiconductor Science and Technology 2002, 17, 270-274.
9. K. Bindu, C. Sudha Kartha, K. P. Vijayakumar, T. Abe and Y. Kashiwaba, “CUINSe₂ Thin Film Preparation Through a New Selenisation Process Using Chemical Bath Deposited Selenium”, Solar Energy Materials & Solar Cells 2003, 79, 67-79.
10. K. Bindu, M. T. S. Nair and, P. K. Nair, “Chemically Deposited Se Thin Films and Their Use as a Planar Source of Selenium for the Formation of Metal Selenide Layers”, Journal of The Electrochemical Society 2006, 153, C526-C534.
11. Chris Eberspacher, James H. Ermer and Kim W. Mitchell, “Process for Making Thin Film Solar Cell”, U.S. Pat. No. 5,045,409.
12. Piero Sferlazzo and Thomas Michael Lampros, “System and Method for Fabricating Thin-Film Photovoltaic Devices”, US20120034764 A1.
13. Serdar Aksu, Jiaxiong Wang and Bulent M. Basol, “Electrochemical Deposition Methods for Fabricating Group IBIIIAVIA Compound Absorber Based Solar Cells”, US20110005586.

It would be advantageous if a solution-based process for the deposition of Cu—In—Ga existed that minimized the requirement of selenization towards the fabrication of a CIGS absorber layer.

### SUMMARY OF THE INVENTION

Disclosed herein is a method to supply additional selenium (Se) to a deposited film of Cu, In, and Ga (CIG) precursors via solution-processing, using a planar Se film that serves as a Se source, upon which subsequent solution-based deposition may be performed. In general, the deposition of Se films can be realized through well-known processing options including chemical bath deposition (CBD), electrochemical deposition, and thermal evaporation, among others. In addition to providing a source of Se from the onset of thermal processing to modulate CIGS films growth, the technology improves interfacial contact at the CIGS/Mo interface by effectively compensating for the challenges associated with deep penetration of Se vapor source during thermal treatment. This strategy reduces resultant CIGS film contamination following thermal processing by circumventing the need to integrate ligand-stabilizing methods for Se incorporation in the solution process and/or thermally labile Se (precursor) sources. The beneficial impact of the technology is independent of the specific Se deposition method. In fact, the requirement for the deposition of uniform Se films can be adequately satisfied through conventional means.

Some aspects of the technology described herein involve the combination of: (1) the ability to provide a Se source (film), (2) upon which Se film subsequent solution-based deposition of Cu—In—Ga metal precursors can proceed. In addition, the same approach can be utilized when the desired film is deposited through multiple stages: the selenium layer can be deposited before deposition of second and subsequent layers. Thus, an additional selenium source improves the interface between the individually deposited Cu—In—Ga layers and improves CIGS absorber layer morphology.

Accordingly, a method is provided for forming a solution-processed metal and mixed-metal selenide, semiconductor using a selenium (Se) film layer. The method, in one aspect, provides a conductive substrate and deposits a first Se film layer over the conductive substrate. A first solution, including a first material set of metal salts, metal complexes, or combinations thereof, is dissolved in a solvent and deposited on the first Se film layer. A first intermediate film comprising metal precursors is formed from corresponding members of the first material set. In one aspect, a plurality of intermediate films is formed using metal precursors from the first material set or a different material set. In another aspect, a second Se film layer is formed overlying the intermediate film(s). Thermal annealing is performed in an environment including hydrogen (H₂), hydrogen selenide (H₂Se), or Se/H₂. As a result, the metal precursors are transformed in the intermediate film(s), and a metal selenide-containing semiconductor is formed.

The first, and any other material sets, may include the following: aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (Ir), iron (Fe), lead (Pb), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn, titanium (Ti), tungsten (W), vanadium (V), zinc (Zn), zirconium (Zr), and combinations thereof.

In another aspect, the first intermediate film is formed on the conductive substrate, and the first Se film layer is deposited over the first intermediate film. Further, a plurality of intermediate films, made from metal precursors from the first material set or other materials sets, may be formed before the deposition of the first Se film layer. Optionally, one or more intermediate film layers may be formed over the first Se film. layer, and as an additional option, a second Se film layer may be deposited over these intermediate films.

Additional details of the above-described methods are provided below.

### BRIEF DESCRIPTION OF THE DRAWINGS

FIG. 1 is a flowchart illustrating a method for forming a solution-processed metal and mixed-metal selenide semiconductor using a. selenium (Se) film layer.

FIG. 2 is a flowchart illustrating a first variation in the method for forming a solution-processed metal and mixed-metal selenide semiconductor using a Se film layer.

FIG. 3 is a flowchart illustrating a second variation in the method for forming a solution-processed metal and mixed-metal selenide semiconductor using a Se film layer.

FIGS. 4A through 4C depict exemplary process steps associated with the method of FIG. 1.

FIGS. 5A through 5D depict exemplary process steps associated with the method of FIG. 2.

FIGS. 6A through 6D depict exemplary process steps associated with the method of FIG. 3.

### DETAILED DESCRIPTION

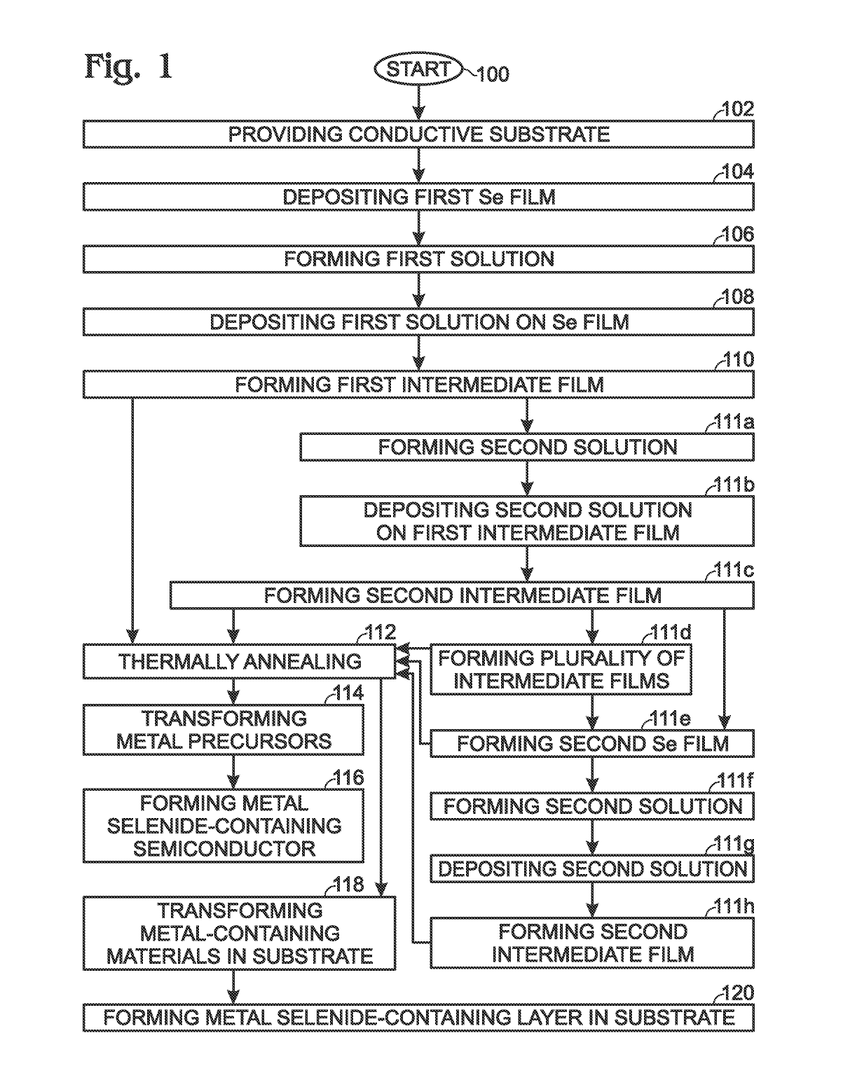

FIG. 1 is a flowchart illustrating a method for forming a solution-processed metal and mixed-metal selenide semiconductor using a selenium (Se) film layer. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. Generally however, the method follows the numeric order of the depicted steps. The method begins at Step 100.

Step 102 provides a conductive substrate. Step 104 deposits a first Se film layer over the conductive substrate. Step 106 forms a first solution including a first material set of metal salts, metal complexes, and combinations thereof, dissolved in a solvent. Some exemplary members of the first material set include aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (Ir), iron (Fe), lead (Pb), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn), titanium (Ti), tungsten (W), vanadium (V), zinc (Zn), zirconium (Zr), and combinations thereof.

As used herein, a solvent is a mixture of chemicals used to affect dissolution of the metal precursors. More generally, the solvents that make up the majority of the solution (liquid phase) to dissolve the metal precursors often include smaller quantities of functional “additives”. These additives may be required to facilitate dissolution of the metal precursors. Furthermore, these additives may be classified as solvents as well.

Step 108 deposits the first solution on the first Se film layer. Step 110 forms a first intermediate film comprising metal precursors, formed from corresponding members of the first material set. Typically, a first proportion of the first intermediate film is metal oxides or mixed metal oxides. As used herein, the term “intermediate film” refers to a film formed as a result of depositing a solution of dissolved metals salts, metal complexes, and combinations thereof (from a solvent) followed by thermal treatment to remove at least a percentage of solvent and furnish a metal-containing precursor film, whereby some first proportion of the film may be metal oxide or mixed-metal oxide. Step 112 thermally anneals in an environment including hydrogen (H₂), hydrogen selenide (H₂Se), Se/H₂, or combinations thereof. As a result, Step 114 transforms the metal precursors in the first intermediate film, and Step 116 forms a metal selenide-containing semiconductor.

The conductive substrate provided in Step 102 is typically selected from a class of materials such as metals, metal alloys, metal oxides, mixed metal oxides, and combinations thereof. Some explicit examples of conductive substrate materials include aluminum, chromium, cobalt, copper, gallium, germanium, gold, indium, iron, lead, molybdenum, nickel, niobium, palladium, platinum, silicon, silver, tantalum, tin, titanium, tungsten, vanadium, zinc, zirconium, stainless steel, indium tin oxide, fluorine-doped tin oxide, and combinations thereof.

In one aspect prior to thermal annealing in Step 112, Step 111a forms a second solution including a second material set selected from the first group, dissolved in a solvent. Step 111b deposits the second solution on the first intermediate film. Step 111c forms a second. intermediate film comprising metal precursors, formed from corresponding members of the second material set. Then, transforming the metal precursors in the first intermediate film in Step 114 includes transforming metal precursors in the first and second intermediate films. In fact, a plurality of intermediate films can be formed overlying the first Sc film layer prior to thermally annealing, as described in Steps 104 through 110 and 111a through 111c, and as represented by Step 111d. In general, the intermediate film may comprise several individually deposited layers of the same, or different, composition.

In another aspect prior to thermally annealing in Step 112, Step 111e forms a second Se film layer overlying the first intermediate film. In one variation prior to thermally annealing in Step 112, Step 111f forms a second solution including a second material set selected from the first group, dissolved in a solvent. Step 111g deposits the second solution on the second Se film layer. Step 111h forms a second intermediate film comprising metal precursors, formed from corresponding members of the second material set. Then, transforming the metal precursors in the first intermediate film in Step 114 includes transforming metal precursors in the first and second intermediate films.

In a different aspect, as a result of thermally annealing in Step 112, Step 118 transforms at least some proportion of metal-containing materials in the conductive substrate, and Step 120 forms a metal selenide-containing layer in the conductive substrate underlying the metal selenide-containing semiconductor.

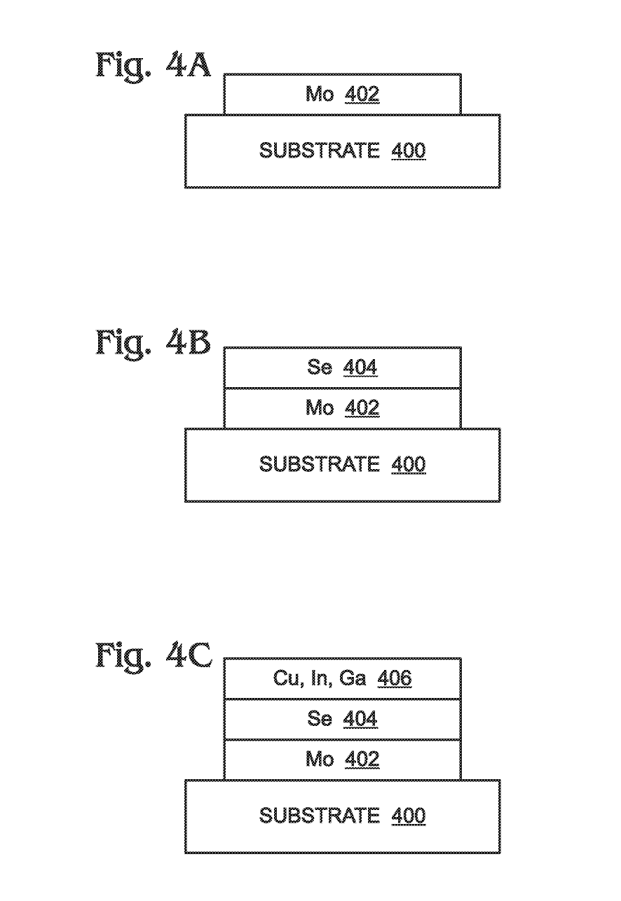

FIGS. 4A through 4C depict exemplary process steps associated with the method of FIG. 1. In FIG. 4B, a film of Se 404 is deposited on a Mo-coated 402 substrate 400. Subsequently, in FIG. 4C, a precursor solution 406 comprising an exemplary mixture of Cu, In, and, Ga salts, metal complexes, and combinations thereof, is deposited on the Se/Mo film, forming an intermediate film. Following the thermal anneal (e.g., with H₂, H₂Se, or H₂/selenium) and subsequent processing/device integration, a functional CIGS solar cell is provided.

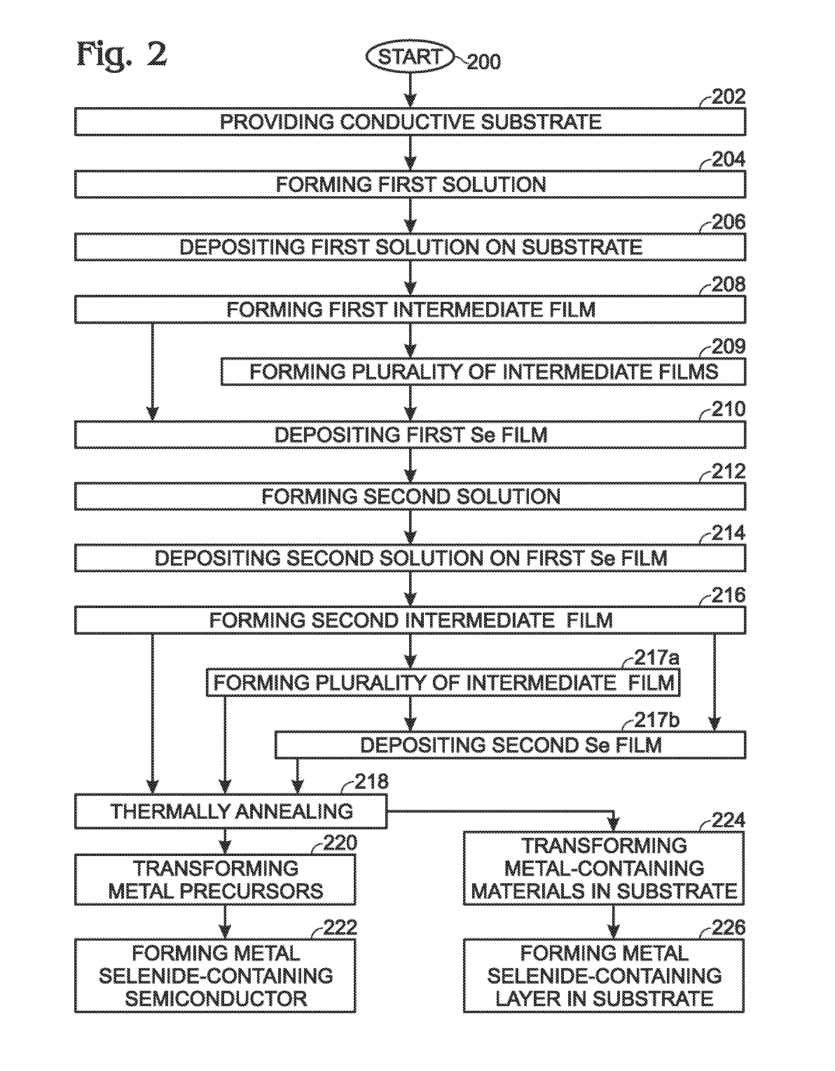

FIG. 2 is a flowchart illustrating a first variation in the method for forming a solution-processed metal and mixed-metal selenide semiconductor using a Se film layer. The method begins at Step 200.

Step 202 provides a conductive substrate. Step 204 forms a first solution including a first material set of metal salts, metal complexes, and combinations thereof, dissolved in a solvent. Some exemplary members of the first material set include aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (Ir), iron (Fe), lead (Pb), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn), titanium (Ti), tungsten (W), vanadium (V), zinc (Zn), zirconium (Zr), and combinations thereof.

Step 206 deposits the first solution on the conductive substrate. Step 208 forms a first intermediate film comprising metal precursors, formed from corresponding members of the first material set. Step 210 deposits a first Se film layer overlying the first intermediate film.

Step 212 forms a second solution including a second material set selected from the first group, dissolved in a solvent. Step 214 deposits the second solution on the first Se film layer. Step 216 forms a second. intermediate film comprising metal precursors, formed from corresponding members of the second material set. Typically, independent proportions of the first and second intermediate films are metal oxides or mixed metal oxides.

Step 218 thermally anneals in an environment including hydrogen (H₂), hydrogen selenide (H₂Se), Se/H₂, or combinations thereof. As a result, Step 220 transforms the metal precursors in the first and second intermediate films, and Step 222 forms a metal selenide-containing semiconductor.

The conductive substrate provided in Step 202 is typically selected from a class of materials such as metals, metal alloys, metal oxides, mixed metal oxides, and combinations thereof. Some explicit examples of conductive substrate materials include aluminum, chromium, cobalt, copper, gallium, germanium, gold, indium, iron, lead, molybdenum, nickel, niobium, palladium, platinum, silicon, silver, tantalum, tin, titanium, tungsten, vanadium, zinc, zirconium, stainless steel, indium tin oxide, fluorine-doped tin oxide, and combinations thereof.

In one aspect, as a result of thermally annealing in Step 218, Step 224 transforms at least some proportion of metal-containing materials in the conductive substrate, and Step 226 forms a metal selenide-containing layer in the conductive substrate underlying the metal selenide-containing semiconductor.

In one aspect prior to thermally annealing in Step 218, Step 217b deposits a second Se film layer overlying the second intermediate film layer. In another aspect prior to thermally annealing in Step 218, Step 209 forms a plurality of intermediate films interposed between the conductive substrate and the first Se film layer. In yet another aspect prior to thermally annealing in Step 218, Step 217a forms a plurality of intermediate films overlying the first Se film layer.

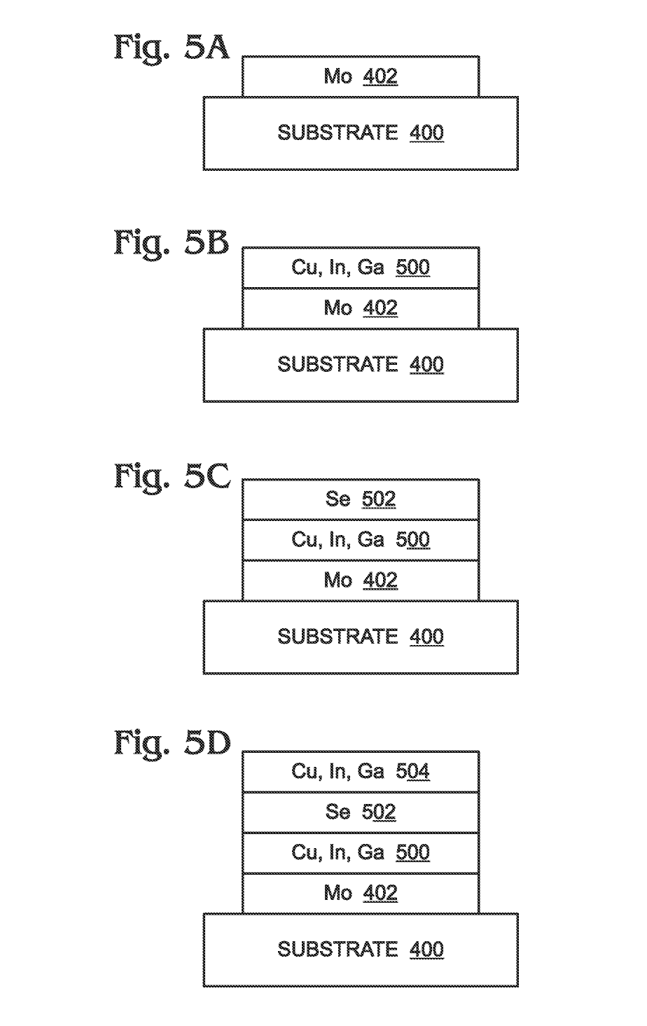

FIGS. 5A through 5D depict exemplary process steps associated with the method of FIG. 2. In FIG. 5B, an exemplary mixture 500 of Cu, In, and, Ga salts, metal complexes, and combinations thereof, is deposited on a Mo film 402, forming an intermediate film. The Mo film 402 is formed over substrate 400. Subsequently, in FIG. 5C, a Se film 502 is formed over intermediate film 500. In FIG. 5D, a solution of metal precursors 504 is deposited over Se film 502, forming an intermediate film. The precursor solution 504 may be the same or different than precursor solution 500. However in this example, the mixture is of Cu, In, and, Ga salts, metal complexes, and combinations thereof. Following thermal annealing (e.g., with H₂, H₂Se, or H₂/selenium) and subsequent processing/device integration, a functional CIGS solar cell is provided.

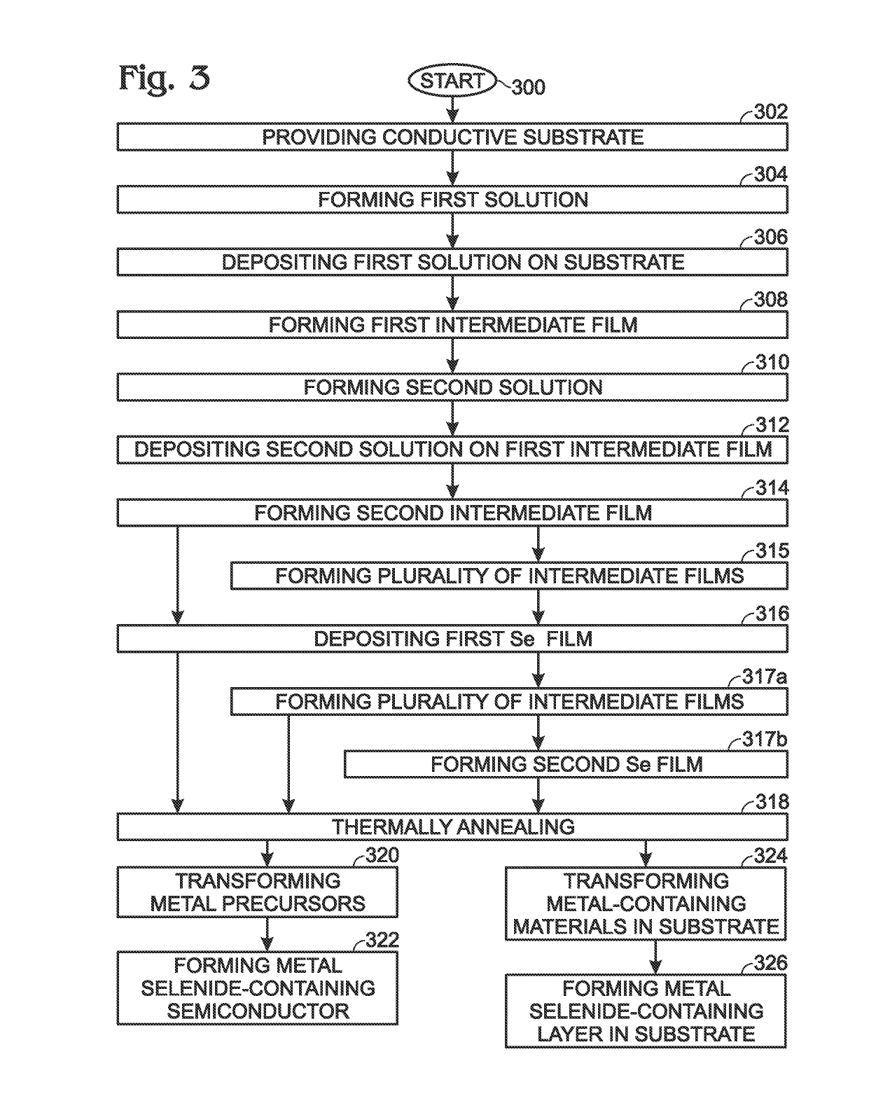

FIG. 3 is a flowchart illustrating a second variation in the method for forming a solution-processed metal and mixed-metal selenide semiconductor using a Se film layer. The method begins at Step 300.

Step 302 provides a conductive substrate. Step 304 forms a. first solution including a first material set of metal salts, metal complexes, and combinations thereof, dissolved in a solvent. Some exemplary members of the first material set include aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (Ir), iron (Fe), lead (Pb), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn), titanium (Ti), tungsten (W), vanadium (V), zinc (Zn), zirconium (Zr), and combinations thereof.

Step 306 deposits the first solution on the conductive substrate. Step 308 forms a first intermediate film comprising metal precursors, formed from corresponding members of the first material set. Step 310 forms a second solution including a second material set selected from the first group, dissolved in a solvent. Step 312 deposits the second solution on the first intermediate film. Step 314 forms a second intermediate film comprising metal precursors, formed from corresponding members of the second material set. Typically, independent proportions of the first and second intermediate films are metal oxides or mixed metal oxides.

Step 316 deposits a first Se film layer overlying the second intermediate film. Step 318 thermally anneals in an environment including hydrogen (H₂), hydrogen selenide (H₂Se), Se/H₂, or combinations thereof. As a result, Step 320 transforms the metal precursors in the first and second intermediate films, and Step 322 forms a metal selenide-containing semiconductor.

The conductive substrate provided in Step 302 is typically selected from a class of materials such as metals, metal alloys, metal oxides, mixed metal oxides, and combinations thereof. Some explicit examples of conductive substrate materials include aluminum, chromium, cobalt, copper, gallium, germanium, gold, indium, iron, lead, molybdenum, nickel, niobium, palladium, platinum, silicon, silver, tantalum, tin, titanium, tungsten, vanadium, zinc, zirconium, stainless steel, indium tin oxide, fluorine-doped tin oxide, and combinations thereof.

In one aspect, as a result of thermally annealing in Step 318, Step 324 transforms at least some proportion of metal-containing materials in the conductive substrate, and Step 326 forms a metal selenide-containing layer in the conductive substrate underlying the metal selenide-containing semiconductor.

In one aspect, prior to thermal annealing in Step 318, Step 315 forms a first plurality of intermediate films interposed between the conductive substrate and the first Se film layer. In another aspect prior to thermal annealing in Step 318, Step 317a forms a second plurality of intermediate films overlying the first Se film layer. Optionally, Step 317b forms a second Se film layer overlying the second plurality of intermediate films prior to thermally annealing in Step 318.

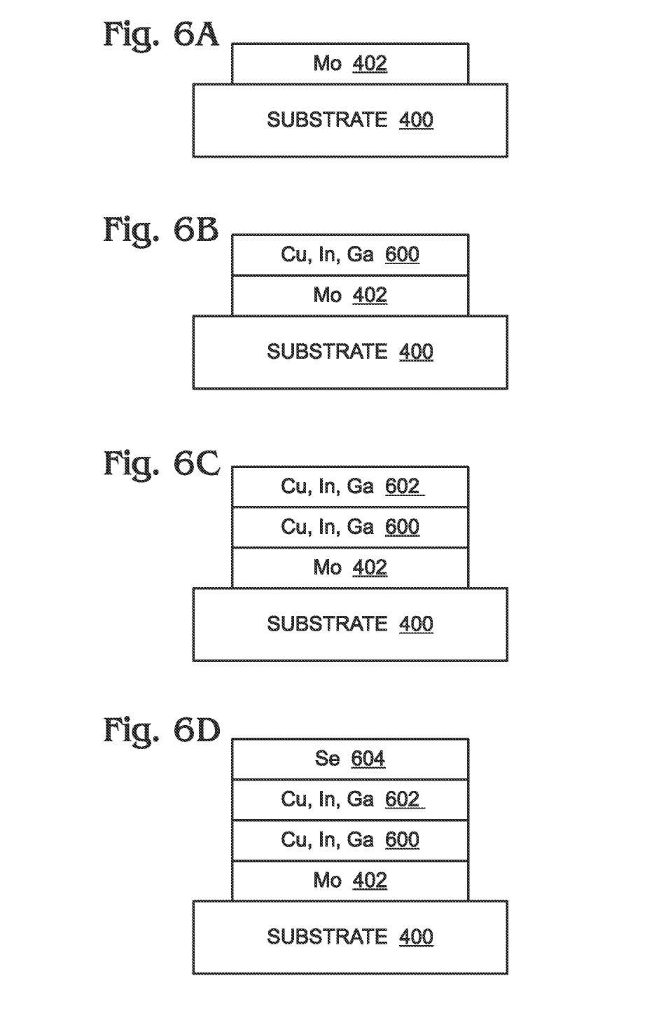

FIGS. 6A through 6D depict exemplary process steps associated with the method of FIG. 3. In FIG. 6B, an exemplary mixture 600 of Cu, In, and, Ga salts, metal complexes, and combinations thereof, is deposited on a Mo film 402 forming an intermediate film. The Mo film 402 is formed over substrate 400. Subsequently, in FIG. 6C, a second precursor solution 602 is deposited over the first precursor solution 600, forming an intermediate film. The precursor solution 602 may be the same or different than precursor solution 600. In this example, precursor solution 602 is a mixture of Cu, In, and, Ga salts, metal complexes, and combinations thereof. In FIG. 6D, a Se film 604 is formed over intermediate film 602. Following thermal annealing (e.g., with H₂, H₂Se, or H₂/selenium) and subsequent processing/device integration, a functional CIGS solar cell is provided.

Conveniently, the strategy for introducing a planar Se supply for CIGS absorber layer fabrication is amenable to nanoparticle (solution-based) approaches as well. In this case, a Se layer can be integrated in a straightforward manner to compensate for stoichiometric Se deficiencies in the as-deposited nanoparticle films.

The processes described herein provides a strategy for fabricating a CIGS absorber layer by depositing a film that functions as a. Se source platform upon which subsequent solution-based deposition of Cu, In, and Ga precursors may proceed. The technology is beneficial in terms of providing both improved CIGS absorber layer morphology and interfacial contacts through an additional Se supply. Conceivably, this approach may provide additional benefits in terms of cost savings due to a reduced thermal processing budget (selenization).

Se film deposition is amenable to conventional processing methods. Conveniently, the CIGS device integration process is performed according to traditional methods following deposition of the Cu, In, and Ga precursor solution and subsequent transformation to CIGS.

As noted above, thermal annealing in the provided atmosphere (H₂, H₂Se and/or Se/H₂) transforms the intermediate film from metal/mixed-metal precursor (e.g., oxide) to metal/mixed metal selenide. During the thermal process, the deposited Se film reacts with the metal precursor (intermediate film or films). Typically, this annealing process proceeds at high temperatures (e.g., greater than 400° C.) and is an important step in furnishing the metal selenide semiconductor composite. However, following the deposition of the individual metal precursor solutions, to form the intermediate films, a lower temperature thermal process may be employed to furnish the intermediate film, as well as to evaporate solvents. In the interests of simplicity, these lower temperature annealing steps are not explicitly mentioned in the methods described by FIGS. 1 through 3.

Processes have been provided for forming a metal and mixed-metal selenide semiconductor using solution-processed metal precursors and a Se film layer. Examples of materials and process variables have been presented to illustrate the invention. However, the invention is not limited to merely these examples. Other variations and embodiments of the invention will occur to those skilled in the art.

We claim:

1. A method for forming a solution-processed metal and mixed-metal selenide semiconductor using a selenium (Se) film layer, the method comprising:
providing a conductive substrate;
depositing a first Se film layer over the conductive substrate;
forming a first solution including a first material set selected from a first group consisting of metal salts; metal complexes, and combinations thereof, dissolved in a solvent;
depositing the first solution on the first Se film layer;
forming a first intermediate film comprising metal precursors, formed from corresponding members of the first material set;
thermally annealing in an environment selected from a group consisting of hydrogen (H₂), hydrogen selenide (H₂Se), Se/H₂, and combinations thereof;
as a result, transforming the metal precursors in the first intermediate film; and,
forming a metal selenide-containing semiconductor.

2. The method of claim 1 wherein the first material set is selected from a group consisting of aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (Ir), iron (Fe), lead (Pb), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn), titanium (Ti), tungsten (W), vanadium (V), zinc (Zn), zirconium (Zr), and combinations thereof.

3. The method of claim 1 wherein the conductive substrate is selected from a class of materials selected from a group consisting of metals, metal alloys, metal oxides, mixed metal oxides, and combinations thereof.

4. The method of claim 3 wherein the conductive substrate is selected from a group of materials consisting of aluminum, chromium, cobalt, copper, gallium, germanium, gold, indium, iron, lead, molybdenum, nickel, niobium, palladium, platinum, silicon, silver, tantalum, tin, titanium, tungsten, vanadium, zinc, zirconium, stainless steel, indium tin oxide, fluorine-doped tin oxide, and combinations thereof.

5. The method of claim 1 wherein forming the first intermediate film comprising metal precursors includes forming a first proportion of the first intermediate film with a material selected from a group consisting of metal oxides and mixed metal oxides.

6. The method of claim 1 further comprising:
prior to thermal annealing, forming a second solution including a second material set selected from the first group, dissolved in a solvent;
depositing the second solution on the first intermediate film;
forming a second intermediate film comprising metal precursors, formed from corresponding members of the second material set; and,
wherein transforming the metal precursors in the first intermediate film includes transforming metal precursors in the first and second intermediate films.

7. The method of claim 1 further comprising:
prior to thermally annealing, forming a second Se film layer over lying the first intermediate film.

8. The method of claim 7 further comprising:
prior to thermally annealing, forming a second solution including a second material set selected from the first group, dissolved in a solvent;
depositing the second solution on the second Se film layer;
forming a second intermediate film comprising metal precursors, formed from corresponding members of the second material set; and,
wherein transforming the metal precursors in the first intermediate film includes transforming metal precursors in the first and second intermediate films.

8. The method of claim 1 further comprising:
prior to thermally annealing, forming a plurality of intermediate films overlying the first Se film layer.

9. The method of claim 1 further comprising:
as a result of thermally annealing, transforming at least some proportion of metal-containing materials in the conductive substrate; and,
forming a metal selenide-containing layer in the conductive substrate underlying the metal selenide-containing semiconductor.

10. A method for forming a solution-processed metal and mixed-metal selenide semiconductor using a selenium (Se) film layer, the method comprising:
providing a conductive substrate;
forming a first solution including a first material set selected from a first group consisting of metal salts, metal complexes, and combinations thereof, dissolved in a solvent;
depositing the first solution on the conductive substrate;
forming a first intermediate film comprising metal precursors, formed from corresponding members of the first material set;
depositing a first Se film layer over the first intermediate film;
forming a second solution including a second material set selected from the first group, dissolved in a solvent;
depositing the second solution on the first Se film layer;
forming a second intermediate film comprising metal precursors, formed from corresponding members of the second material set;
thermally annealing in an environment selected from a group consisting of hydrogen (H₂), hydrogen selenide (H₂Se), Se/H₂, and combinations thereof;
as a result, transforming metal precursors in the first and second intermediate films; and,
forming a metal selenide-containing semiconductor.

11. The method of claim 10 wherein the first and second material sets are independently selected from a group consisting of aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (ir), iron (Fe), lead (Ph), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn), titanium (Ti), tungsten (W), vanadium (V), zinc (Zn), zirconium (Zr), and combinations thereof.

12. The method of claim 10 wherein the conductive substrate is selected from a class of materials selected from a group consisting of metals, metal alloys, metal oxides, mixed metal oxides, and combinations thereof.

13. The method of claim 12 wherein the conductive substrate is selected from a group of materials consisting of aluminum, chromium, cobalt, copper, gallium, germanium, gold, indium, iron, lead, molybdenum, nickel, niobium, palladium, platinum, silicon, silver, tantalum, tin, titanium, tungsten, vanadium, zinc, zirconium, stainless steel, indium tin oxide, fluorine-doped tin oxide, and combinations thereof.

14. The method of claim 10 wherein forming the first and second intermediate films includes independently forming independent proportions of the first and second intermediate films with a material selected from a group consisting of metal oxides and mixed metal oxides.

15. The method of claim 10 further comprising:
as a result of thermally annealing, transforming at least some proportion of metal-containing materials in the conductive substrate; and,
forming a metal selenide-containing layer in the conductive substrate underlying the metal selenide-containing semiconductor.

16. The method of claim 10 further comprising:
prior to thermally annealing, depositing a second Se film layer overlying the second intermediate film layer.

17. The method of claim 10 further comprising:
prior to thermally annealing, forming a plurality of intermediate films interposed between the conductive substrate and the first Se film layer.

18. The method of claim 17 further comprising:
prior to thermally annealing, forming a plurality of intermediate films overlying the first Se film layer.

19. A method for forming a solution-processed metal and mixed-metal selenide semiconductor using a selenium (Se) film layer, the method comprising:
providing a conductive substrate;
forming a first solution including a first material set selected from a first group consisting of metal salts, metal complexes, and combinations thereof, dissolved in a solvent;
depositing the first solution on the conductive substrate;
forming a first intermediate film comprising metal precursors, formed from corresponding members of the first material set;
forming a second solution including a second material set selected from the first group, dissolved in a solvent;
depositing the second solution on the first intermediate film;
forming a second intermediate film comprising metal precursors, formed from corresponding members of the second material set;
depositing a first Se film layer over the second intermediate film;
thermally annealing in an environment selected from a group consisting of hydrogen (H₂), hydrogen selenide (H₂Se), Se/H₂, and combinations thereof;
as a result, transforming metal precursors in the first and second intermediate films; and,
forming a metal selenide-containing semiconductor.

20. The method of claim 19 wherein the first and second material sets are independently selected from a group consisting of aluminum (Al), antimony (Sb), arsenic (As), bismuth (Bi), cadmium (Cd), cesium (Cs), chromium (Cr), cobalt (Co), copper (Cu), gallium (Ga), germanium (Ge), gold (Au), indium (In), iridium (Ir), iron (Fe), lead (Pb), lithium (Li), manganese (Mn), mercury (Hg), molybdenum (Mo), nickel (Ni), niobium (Nb), osmium (Os), palladium (Pd), platinum (Pt), potassium (K), rhodium (Rh), ruthenium (Ru), silver (Ag), sodium (Na), tantalum (Ta), tin (Sn), titanium (Ti), tungsten (W), vanadium (V), zinc (Zn), zirconium (Zr), and combinations thereof.

21. The method of claim 19 wherein the conductive substrate is selected from a class of materials selected from a group consisting of metals, metal alloys, metal oxides, mixed metal oxides, and combinations thereof.

22. The method of claim 21 wherein the conductive substrate is selected from a group of materials consisting of aluminum, chromium, cobalt, copper, gallium, germanium, gold, indium, iron, lead, molybdenum, nickel, niobium, palladium, platinum, silicon, silver, tantalum, tin, titanium, tungsten, vanadium, zinc, zirconium, stainless steel, indium tin oxide, fluorine-doped tin oxide, and combinations thereof.

23. The method of claim 19 wherein forming the first and second intermediate films includes independently forming independent proportions of the first and second intermediate films with a material selected from a group consisting of metal oxides and mixed metal oxides.

24. The method of claim 19 further comprising:
prior to thermal annealing, forming a first plurality of intermediate films interposed between the conductive substrate and the first Se film layer.

25. The method of claim 19 further comprising:
prior to thermal annealing, forming a second plurality of intermediate films overlying the first Se film layer.

26. The method of claim 25 further comprising:
prior to thermally annealing, forming a second Se film layer overlying the second plurality of intermediate films.

27. The method of claim 19 further comprising:
as a result of thermally annealing, transforming at least some proportion of metal-containing materials in the conductive substrate; and,
forming a metal selenide-containing layer in the conductive substrate underlying the metal selenide-containing semiconductor.
